(19) United States
(12) Patent Application Publication
(10) Pub. No.: US 2011/0259398 A1
(43) Pub. Date: Oct. 27, 2011

(54) THIN FILM SOLAR CELL AND METHOD FOR MANUFACTURING THE SAME

(76) Inventors: Soohyun Kim, Seoul (KR); Sehwon Ahn, Seoul (KR); Hongcheol Lee, Seoul (KR)

(21) Appl. No.: 13/176,673

(22) Filed: Jul. 5, 2011

(30) Foreign Application Priority Data
Jan. 14, 2011 (KR) 10-2011-0003850

(51) Int. Cl. H01L 31/052; H01L 31/18

(52) U.S. Cl. 136/246; 438/72; 257/E31.127

(57) ABSTRACT

A thin film solar cell and a method for manufacturing the same are discussed. The thin film solar cell includes a plurality of cells positioned on a substrate. Each of the plurality of cells includes a first electrode positioned on one surface of the substrate, at least one photoelectric conversion unit positioned on the first electrode, a back reflection layer including a first reflection layer contacting the at least one photoelectric conversion unit and a second reflection layer having an opening exposing a portion of the first reflection layer, and a second electrode positioned on the back reflection layer. The second reflection layer contacts the first reflection layer. The second electrode is electrically connected to the first reflection layer through the opening.

This application claims priority to and the benefit of Korean Patent Application No. 10-2011-0003850 filed in the Korean Intellectual Property Office on Jan. 14, 2011, the entire contents of which are incorporated herein by reference.

### BACKGROUND OF THE INVENTION

1. Field of the Invention

Embodiments of the invention relate to a thin film solar cell and a method for manufacturing the same.

2. Description of the Related Art

Solar cells use an infinite energy source, i.e., the sun, scarcely produce pollution materials in an electricity generation process, and have a very long life span equal to or longer than 20 years. Furthermore, the solar cells have been particularly spotlighted because of a large ripple effect on the solar related industries. Thus, many countries have fostered the solar cells as the next generation industry.

Most of the solar cells have been manufactured based on a single crystal silicon wafer or a polycrystalline silicon wafer. In addition, thin film solar cells using silicon have been manufactured in lesser quantities.

The solar cells have the problem of a very high electricity generation cost compared to other energy sources. Thus, the electricity generation cost of the solar cells has to be greatly reduced so as to meet a future demand for clean energy.

However, because a bulk solar cell manufactured based on the single crystal silicon wafer or the polycrystalline silicon wafer now uses a raw material having a thickness of at least 150 μm, the cost of the raw material, i.e., silicon, makes up most of the production cost of the bulk solar cell. Further, because the supply of the raw material does not meet the rapidly increasing demand, it is difficult to reduce the production cost of the bulk solar cell.

On the other hand, because a thickness of the thin film solar cell is less than 2 μm, an amount of raw material used in the thin film solar cell is much less than an amount of raw material used in the bulk solar cell. Thus, the thin film solar cell is more advantageous than the bulk solar cell in terms of the electricity generation cost, i.e., the production cost. However, an electricity generation performance of the thin film solar cell is one half of an electricity generation performance of the bulk solar cell for a given area.

The efficiency of the solar cell is generally expressed by a magnitude of electric power obtained at a light intensity of 100 mW/cm² in terms of percentage. The efficiency of the bulk solar cell is approximately 12% to 20%, and the efficiency of the thin film solar cell is approximately 8% to 9%. In other words, the efficiency of the bulk solar cell is greater than the efficiency of the thin film solar cell. Accordingly, much stepped up effort to increase the efficiency of the thin film solar cell is being made.

The most basic structure of the thin film solar cell is a single junction structure. A single junction thin film solar cell has a structure in which a photoelectric conversion unit including an intrinsic semiconductor layer for light absorption, a p-type doped layer, and an n-type doped layer are formed on a substrate. The p-type doped layer and the n-type doped layer are respectively formed on and under the intrinsic semiconductor layer, thereby forming an inner electric field for separating carriers produced by solar light.

The increase in the efficiency of the thin film solar cell requires an increase in a current density flowing in the thin film solar cell. Thus, the thin film solar cell has to be configured, so that solar light passing through the intrinsic semiconductor layer is reflected back towards the intrinsic semiconductor layer and then is absorbed in the intrinsic semiconductor layer. As a result, the thin film solar cell includes a back reflection layer for increasing a light absorptance of the intrinsic semiconductor layer, thereby increasing the current density.

### SUMMARY OF THE INVENTION

In one aspect, there is a thin film solar cell including a plurality of cells positioned on a substrate, wherein each of the plurality of cells includes a first electrode positioned on one surface of the substrate, at least one photoelectric conversion unit positioned on the first electrode, a back reflection layer including a first reflection layer contacting the at least one photoelectric conversion unit and a second reflection layer having an opening exposing a portion of the first reflection layer, the second reflection layer contacting the first reflection layer, and a second electrode positioned on the back reflection layer, the second electrode being electrically connected to the first reflection layer through the opening.

The first reflection layer may contain aluminum-doped zinc oxide (AZO) with conductivity or boron-doped zinc oxide (BZO) with conductivity. The second electrode may contain aluminum contacting the first reflection layer through the opening.

The first reflection layer may have a thickness equal to or less than about 100 nm.

The second reflection layer may be formed of a material obtained by mixing a medium with a white pigment reflecting light of a long wavelength band equal to or longer than about 600 nm. The white pigment may contain at least one of an oxide, such as titanium dioxide (TiO₂) and barium sulfate (BaSO₄), a nitride, and a carbide. The second reflection layer may contain one of a white paint containing the white pigment, a white foil, and ethyl vinyl acetate (EVA) foil.

The opening may have a circle shape, a quadrangle shape, or a rectangle shape. At least one opening may be positioned on one second electrode.

A width of the opening may be less than a width of the second electrode. A length of the opening may be less than a length of the second electrode.

In another aspect, there is a method for manufacturing a thin film solar cell including forming a first electrode on a substrate, forming at least one photoelectric conversion unit on the first electrode, forming a first reflection layer having conductivity on the at least one photoelectric conversion unit and forming a second reflection layer having an opening exposing a portion of the first reflection layer on the first reflection layer to thereby form a back reflection layer, and forming a second electrode, that is electrically connected to the first reflection layer through the opening, on the second reflection layer.

According to the above-described characteristics, because excellent scattering effect may be obtained by the white pigment contained in the second reflection layer, it is possible to effectively achieve light trapping, and a thickness of the photoelectric conversion unit may be reduced.

Further, because the second electrode is electrically connected to the first reflection layer through the opening of the second reflection layer, the conductivity of the second electrode formed using only aluminum that is often cheaper than silver may be similar to the conductivity of a second electrode formed using both silver and aluminum.

Accordingly, the thickness of the first reflection layer does not have to increase so as to obtain the conductivity similar to the second electrode formed using both silver and aluminum. As a result, time and cost required to deposit the first reflection layer may be reduced. Further, a loss generated when light of the long wavelength band is transmitted by the first reflection layer and is absorbed in the first reflection layer may be minimized.

Further, it is possible to prevent or reduce a reflection loss resulting from a surface plasmon absorption phenomenon generated at the interface between the first reflection layer and the second reflection layer when silver is used to form the second reflection layer. Therefore, the embodiment of the invention may achieve a reflectance similar to a reflectance obtained when silver is used to form the second reflection layer.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a partial cross-sectional view of a thin film solar cell according to an example embodiment of the invention;

FIGS. 2 and 3 are graphs illustrating a reflectance and a haze depending on the type of a back reflection layer according to related arts;

FIG. 4 is a graph illustrating an absorptance of a first reflection layer formed of aluminum-doped zinc oxide (AZO) over wavelength;

FIGS. 5 to 8 relate to a method for manufacturing a thin film solar cell according to an example embodiment of the invention; and

FIG. 9 is a plane view of FIG. 8 illustrating an opening according to an example embodiment of the invention.

### DETAILED DESCRIPTION OF THE EMBODIMENTS

The invention will be described more fully hereinafter with reference to the accompanying drawings, in which example embodiments of the inventions are shown. This invention may, however, be embodied in many different forms and should not be construed as limited to the embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, it will be understood that when an element such as a layer, film, region, or substrate is referred to as being “entirely” on another element, it may be on the entire surface of the other element and may not be on a portion of an edge of the other element.

Reference will now be made in detail to embodiments of the invention, examples of which are illustrated in the accompanying drawings.

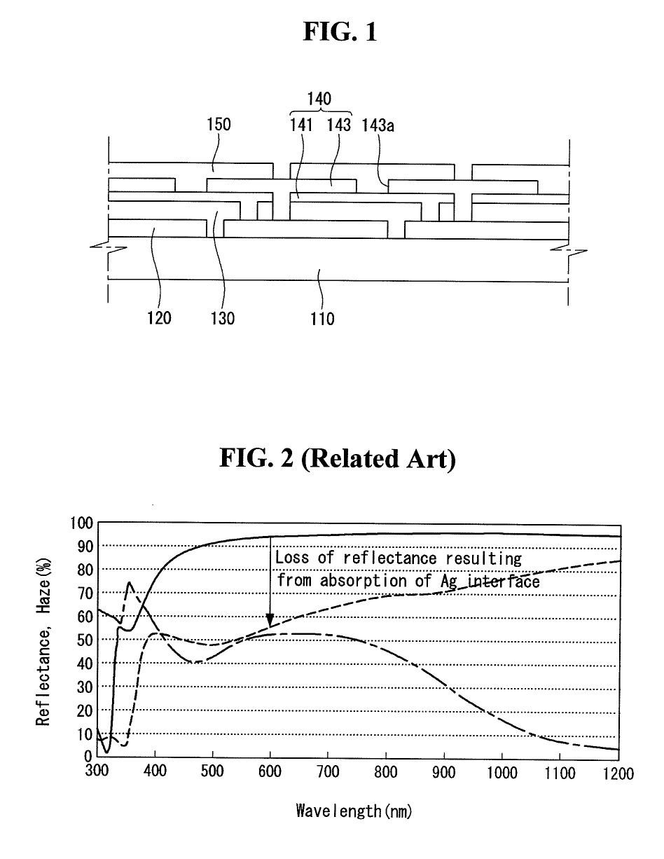

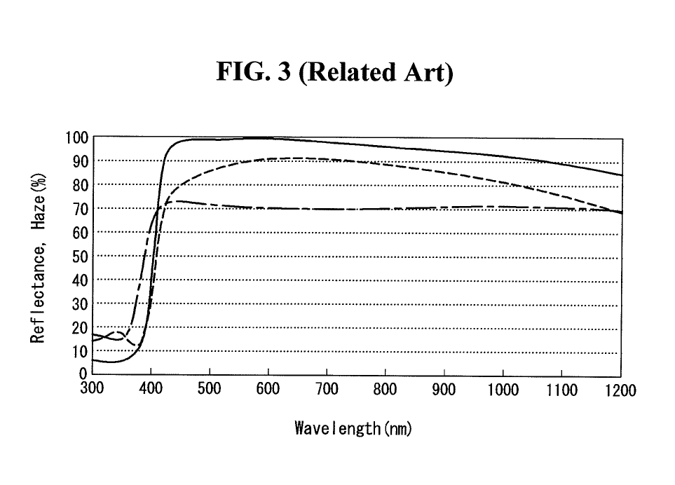

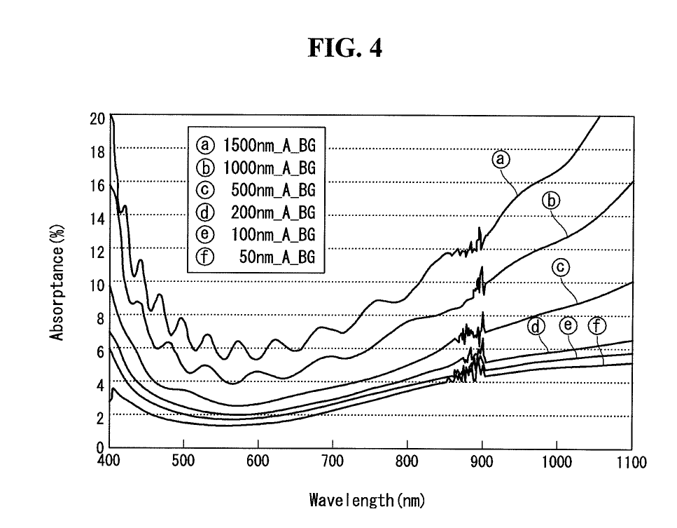

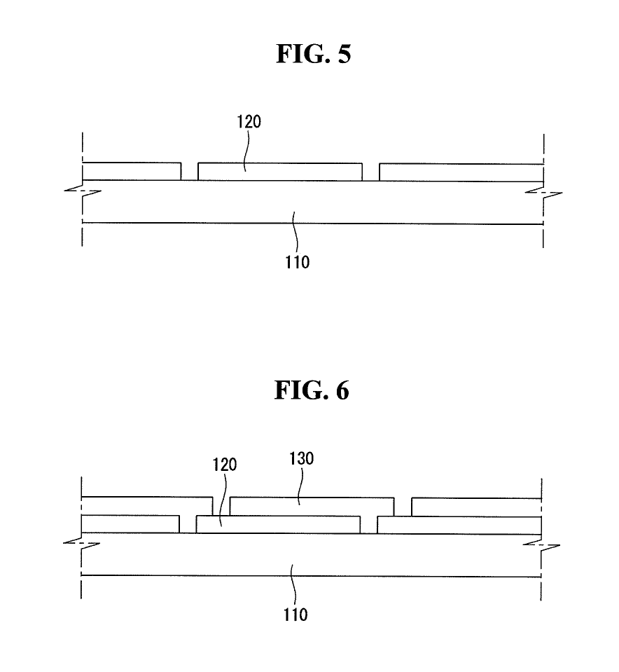

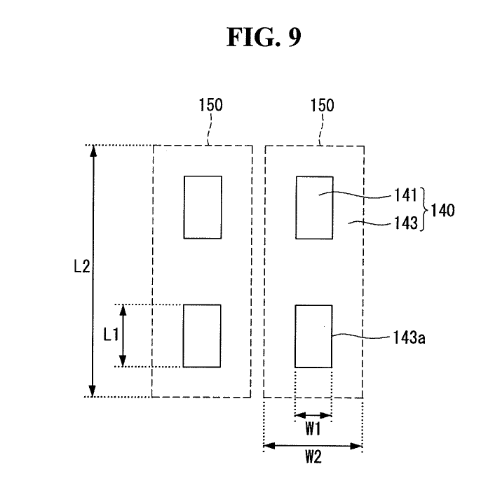

FIG. 1 is a partial cross-sectional view of a thin film solar cell according to an example embodiment of the invention. FIGS. 2 and 3 are graphs illustrating a reflectance and a haze depending on the type of a back reflection layer according to related arts. FIG. 4 is a graph illustrating an absorptance of a first reflection layer formed of aluminum-doped zinc oxide (AZO) over wavelength. FIGS. 5 to 8 relate to a method for manufacturing the thin film solar cell according to the example embodiment of the invention. FIG. 9 is a plane view of FIG. 8 illustrating an opening according to an example embodiment of the invention.

A thin film solar cell according to an example embodiment of the invention has a superstrate structure, in which light is incident through a substrate 110, with reference to the accompanying drawings.

More specifically, the thin film solar cell having the superstrate structure includes a substrate 110, which may be formed of a transparent material, such as glass or transparent plastic, etc., a transparent conductive oxide (TCO) electrode 120 positioned on the substrate 110, a photoelectric conversion unit 130 positioned on the TCO electrode 120, a back reflection layer 140 positioned on the photoelectric conversion unit 130, and a back electrode 150 positioned on the back reflection layer 140. In the embodiment of the invention, the TCO electrode 120 may be referred to as a first electrode and the back electrode 150 may be referred to as a second electrode.

The TCO electrode 120 is formed on the substrate 110 and is electrically connected to the photoelectric conversion unit 130. Thus, the TCO electrode 120 collects carriers (for example, holes) produced by light and outputs the carriers. Further, the TCO electrode 120 may serve as an anti-reflection layer.

An upper surface of the TCO electrode 120 may be textured to form a textured surface having a plurality of uneven portions, each of which may have a non-uniform pyramid shape. When the upper surface of the TCO electrode 120 is the textured surface, a light reflectance of the TCO electrode 120 is reduced. Hence, a light absorptance of the TCO electrode 120 increases, and efficiency of the thin film solar cell is improved. Heights of the uneven portions of the TCO electrode 120 may be within the range of about 1 μm to 10 μm.

The TCO electrode 120 requires high transmittance and high electrical conductivity, so as to transmit most of light incident on the substrate 110 and smoothly pass through electric current. For this, the TCO electrode 120 may be formed of at least one selected from the group consisting of indium tin oxide (ITO), tin-based oxide (for example, SnO₂), AgO, ZnO—Ga₂O₃ (or ZnO—Al₂O₃), fluorine tin oxide (FTO), and a combination thereof. A specific resistance of the TCO electrode 120 may be approximately 10⁻² Ω·cm to 10⁻¹ Ω·cm.

The photoelectric conversion unit 130 may be applied to a single junction thin film solar cell, a double junction thin film solar cell, or a triple junction thin film solar cell.

In the single junction thin film solar cell, the photoelectric conversion unit 130 may be formed of hydrogenated amorphous silicon (a-Si:H). The photoelectric conversion unit 130 may have an optical band gap of about 1.7 eV and may mostly absorb light of a short wavelength band such as near ultraviolet light, purple light, and/or blue light.

The photoelectric conversion unit 130 includes a semiconductor layer (for example, a p-type doped layer) of a first conductive type, an intrinsic semiconductor layer, and a semiconductor layer (for example, an n-type doped layer) of a second conductive type opposite the first conductive type, that are sequentially stacked on the TCO electrode 120.

The p-type doped layer may be formed by mixing a gas containing impurities of a group III element such as boron (B), gallium (Ga), and indium (In) with a raw gas containing silicon (Si). In the embodiment of the invention, the p-type doped layer may be formed of hydrogenated amorphous silicon (a-Si:H) or using other materials.

The intrinsic semiconductor layer prevents or reduces a recombination of carriers and absorbs light. The carriers (i.e., electrons and holes) are mostly produced in the intrinsic semiconductor layer. The intrinsic semiconductor layer may have a thickness of about 200 nm to 300 nm. The intrinsic semiconductor layer may be formed of hydrogenated amorphous silicon (a-Si:H) or using other materials. For example, the intrinsic semiconductor layer may be formed of microcrystalline silicon (μc-Si) or hydrogenated microcrystalline silicon (μc-Si:H).

The n-type doped layer may be formed by mixing a gas containing impurities of a group V element such as phosphorus (P), arsenic (As), and antimony (Sb) with a raw gas containing silicon (Si).

The photoelectric conversion unit 130 may be formed using a chemical vapor deposition (CVD) method such as a plasma enhanced CVD (PECVD) method.

The p-type doped layer and the n-type doped layer of the photoelectric conversion unit 130 form a p-n junction with the intrinsic semiconductor layer interposed therebetween. Hence, electrons and holes produced in the intrinsic semiconductor layer are separated from each other by a contact potential difference resulting from a photovoltaic effect and move in different directions. For example, the holes move to the TCO electrode 120 through the p-type doped layer, and the electrons move to the back electrode 150 through the n-type doped layer.

In an embodiment of the invention with the double junction thin film solar cell, two photoelectric conversion units are formed between the TCO electrode 120 and the back reflection layer 140.

Therein, one of the two photoelectric conversion units positioned closer to the TCO electrode 120 than the back reflection layer 140 may be formed of hydrogenated amorphous silicon (a-Si:H) or using other materials. Further, the other photoelectric conversion unit positioned closer to the back reflection layer 140 than the TCO electrode 120 may be formed of hydrogenated microcrystalline silicon (μc-Si:H) or using other materials.

The photoelectric conversion unit formed of μc-Si:H may have an optical band gap of about 1.1 eV and may mostly absorb light of a long wavelength band from red light to near infrared light.

The photoelectric conversion unit formed of μc-Si:H may include a p-type doped layer, an intrinsic semiconductor layer, and an n-type doped layer, in the same manner as the photoelectric conversion unit formed of a-Si:H.

The back reflection layer 140 reflects light passing through the photoelectric conversion unit 130 back toward the photoelectric conversion unit 130, thereby improving an operation efficiency of the photoelectric conversion unit 130. The back reflection layer 140 includes a first reflection layer 141 and a second reflection layer 143.

A related art back reflection layer used a double-layered structure (hereinafter, referred to as a first related art structure) including a first reflection layer formed of aluminum-doped zinc oxide (AZO) and a second reflection layer formed of silver (Ag). Alternatively, the related art back reflection layer used a double-layered structure (hereinafter, referred to as a second related art structure) including a first reflection layer formed of AZO and a second reflection layer formed of a white paint.

In the first related art structure, because the first reflection layer can be manufactured to be thin, for example, in a thickness of about 50 nm to 200 nm, the investment cost in equipment is reduced and the manufacturing process is simple. Further, because the first related art structure has a compound electrode structure of silver and aluminum, the back reflection layer having the first related art structure has excellent conductivity.

However, in the first related art structure, a reflection loss is generated because of a surface plasmon absorption phenomenon generated at an interface between the first reflection layer and the second reflection layer. Further, a trapping effect of light is relatively reduced because of weak scattering effect of reflected light.

In other words, as shown in FIG. 2, a reflectance (indicated by the dotted line) of the back reflection layer of the first related art structure including the first reflection layer formed of AZO and the second reflection layer formed of Ag is less than a reflectance (indicated by the solid line) of a back reflection layer including only a reflection layer formed of Ag, because reflection loss is generated at the interface between the first reflection layer and the second reflection layer of the first related art structure as discussed above.

In FIG. 2, the dashed dotted line indicates haze values indicating the scattering effect in the back reflection layer of the first related art structure.

In the second related art structure, because there is no reflection loss at an interface between the first reflection layer and the second reflection layer, the back reflection layer may obtain a reflectance level similar to one formed of only silver, which is a material having a high reflectance. Further, because the back reflection layer of the second related art structure does not use silver, the material cost may be reduced. The back reflection layer of the second related art structure may achieve the effective light trap using high scattering characteristic of the white paint.

However, because the second reflection layer of the second related art structure does not use a conductive material such as silver and aluminum, the first reflection layer has to be manufactured to be thick, for example, in a thickness of 1 μm to 2 μm, so as to reduce a resistance of the first reflection layer. Thus, because a low pressure CVD (LPCVD) method is required to deposit the first reflection layer for long time, the investment cost in equipment increases. Further, an absorption loss is generated in light of a long wavelength band generated in the thick first reflection layer.

In other words, as shown in FIG. 3, a reflectance (indicated by the dotted line) of the back reflection layer of the second related art structure including the first reflection layer formed of AZO and the second reflection layer formed of the white paint is less than a reflectance (indicated by the solid line) of a back reflection layer including only a reflection layer formed of silver. Because the absorption loss is generated in light of the long wavelength band generated in the first reflection layer of the second related art structure as discussed above.

In FIG. 3, the dashed dotted line indicates haze values indicating the scattering effect in the back reflection layer of the second related art structure. In this instance, as shown in FIGS. 2 and 3, the scattering effect of the back reflection layer including the second reflection layer formed of the white paint is more excellent than the scattering effect of the back reflection layer including only the reflection layer formed of Ag.

FIG. 4 is a graph illustrating light absorption characteristic of the first reflection layer formed of AZO. When the first reflection layer is manufactured to be thin in a thickness equal to or less than about 200 nm, an absorptance of the first reflection layer is kept at a low level as indicated by solid lines \textcircled{d}, \textcircled{e}, and \textcircled{f} of FIG. 4. On the other hand, when the thickness of the first reflection layer increases to a value equal to or greater than about 1 μm, the absorptance of the first reflection layer in the long wavelength band exceeds about 10% as indicated by solid lines \textcircled{a} and \textcircled{b} of FIG. 4.

In FIG. 4, the solid lines \textcircled{a}, \textcircled{b}, \textcircled{c}, \textcircled{d}, \textcircled{e}, and \textcircled{f} respectively indicate the absorptances of the first reflection layer when the thickness of the first reflection layer formed of AZO is 50 nm, 100 nm, 200 nm, 500 nm, 1,000 nm, and 1,500 nm.

Accordingly, it may be preferable, but not required, that the first reflection layer formed of AZO has as thin a thickness as possible so as to efficiently use the second reflection layer formed of the white paint.

More specifically, in the embodiment of the invention, a reflection loss is prevented or reduced from being generated at an interface between the first reflection layer and the second reflection layer, and the back reflection layer increasing the scattering effect is provided. Further, because the first reflection layer formed of AZO is manufactured to be thin, an amount of light absorbed in the first reflection layer is reduced.

In the embodiment of the invention, the back reflection layer 140 includes the first reflection layer 141 formed of AZO or boron-doped zinc oxide (BZO) and the second reflection layer 143 containing a white paint.

The second reflection layer 143 is formed of a material obtained by mixing a medium with a white pigment that reflects light of a predetermined wavelength, for example, a long wavelength band equal to or longer than about 600 nm. The white pigment may contain at least one of an oxide, such as titanium dioxide (TiO₂) and barium sulfate (BaSO₄), a nitride, and a carbide. The second reflection layer 143 may contain one of a white paint containing the white pigment, a white foil, and ethyl vinyl acetate (EVA) foil. In other embodiments of the invention, a combination of one or more of thereof may be included.

The basic structure of the back reflection layer 140 including the first reflection layer 141 formed of AZO or BZO and the second reflection layer 143 formed of the white paint is different to the above-described second related art structure. That is, in the embodiment of the invention, the second reflection layer 143 includes an opening 143a instead of an increase in a thickness of the first reflection layer 141, and the back electrode 150 contacts the first reflection layer 141 through the opening 143a, thereby providing the conductivity.

The opening 143a may have various shapes such as a circle, an oval, a triangle, a quadrangle, and a rectangle. FIG. 8 shows the opening 143a having the rectangle shape. Other shapes or forms are possible.

As shown in FIG. 9, at least one opening 143a may be formed in one back electrode 150. A width W1 of the opening 143a is less than a width W2 of the back electrode 150, and a length L1 of the opening 143a is less than a length L2 of the back electrode 150.

The back electrode 150 is formed using aluminum contacting the first reflection layer 141 through the opening 143a.

As discussed above, in the thin film solar cell according to the embodiment of the invention, because the back electrode 150 contacts the first reflection layer 141 through the opening 143a, silver for providing the conductivity does not have to be used to form the back reflection layer 140. Further, the first reflection layer 141 formed of AZO or BZO may be manufactured to be thin. Even if the first reflection layer 141 is manufactured in a thickness equal to or less than about 100 nm, the conductivity may be sufficiently provided.

In the thin film solar cell having the above-described configuration, the excellent scattering effect may be obtained because of the white pigment contained in the second reflection layer 143. Therefore, it is possible to effectively achieve the light trapping, and a thickness of the photoelectric conversion unit 130 may be reduced.

Further, because the back electrode 150 is electrically connected to the first reflection layer 141 through the opening 143a of the second reflection layer 143, the conductivity of the back electrode 150 formed using only aluminum that is often cheaper than silver may be similar to the conductivity of the back electrode formed using both silver and aluminum.

Accordingly, the thickness of the first reflection layer 141 does not have to increase so as to obtain the conductivity similar to the back electrode formed using both silver and aluminum. As a result, time and cost required to deposit the first reflection layer 141 may be reduced. Further, a loss occurring when light of the long wavelength band is transmitted in the first reflection layer 141 and is absorbed in the first reflection layer 141 may be minimized.

It is possible to prevent or reduce the reflection loss resulting from the surface plasmon absorption phenomenon generated at the interface between the first reflection layer and the second reflection layer when silver is used to form the second reflection layer. Therefore, the embodiment of the invention uses a white pigment to achieve a reflectance that is similar to a reflectance obtained when silver is used to form the second reflection layer 143.

A method for manufacturing the thin film solar cell having the above-described configuration is described below.

First, as shown in FIG. 5, a transparent conductive oxide (TCO) layer is deposited on the entire surface of a substrate 110. The TCO layer may be formed of metal oxide, for example, at least one selected among tin dioxide (SnO₂), zinc oxide (ZnO), and indium tin oxide (ITO). Alternatively, the TCO layer may be formed of a mixture obtained by mixing one or more impurities with a metal oxide.

Subsequently, the TCO layer is patterned to form a plurality of TCO electrodes 120 in an electricity generation region of the substrate 110.

The patterning process for the TCO layer may be performed through a first scribing process. The first scribing process is a process for irradiating a laser beam from a lower part of the substrate 110 toward the substrate 110 to evaporate the TCO layer of a predetermined region. Thus, the first scribing process is performed to form the plurality of TCO electrodes 120, which are spaced apart from one another at a uniform distance therebetween, in the electricity generation region.

After the first scribing process is performed, a silicon thin film layer is deposited on the substrate 110. The silicon thin film layer is filled in a space between the TCO electrodes 120.

The silicon thin film layer may be formed using an amorphous silicon-based thin film or a tandem silicon thin film layer obtained by stacking an amorphous silicon-based thin film and a microcrystalline silicon-based thin film.

When the silicon thin film layer is formed using the tandem silicon thin film layer, a middle TCO layer may be further formed between the amorphous silicon-based thin film and the microcrystalline silicon-based thin film. As discussed above, the embodiment of the invention does not limit the structure of the silicon thin film layer, and the silicon thin film layer may be formed based on various structures.

Subsequently, as shown in FIG. 6, the silicon thin film layer is patterned to form a plurality of photoelectric conversion units 130 in the electricity generation region. The patterning process for the silicon thin film layer may be performed through a second scribing process.

An output power of a laser used in the second scribing process is lower than an output power of a laser used in the first scribing process.

Accordingly, when the second scribing process for irradiating a laser beam from the lower part of the substrate 110 toward the substrate 110 is performed, the TCO electrodes 120 of the electricity generation region are not evaporated, but the silicon thin film layer on the TCO electrodes 120 is evaporated and removed. Hence, the plurality of photoelectric conversion units 130, which are spaced apart from one another at a uniform distance therebetween, are formed in the electricity generation region. Additionally, portions of the TCO electrodes 120 are exposed thereby.

After the second scribing process is performed, a transparent conductive layer is formed on the substrate 110. The transparent conductive layer is filled in a space between the photoelectric conversion units 130. The transparent conductive layer may be formed of AZO or BZO and may have a thickness equal to or less than about 100 nm. Additionally, the transparent conductive layer is electrically connected to the TCO electrodes 120 thereby. In an embodiment of the invention, the transparent conductive layer may be contacted to the exposed portions of the TCO electrodes 120, although such is not required.

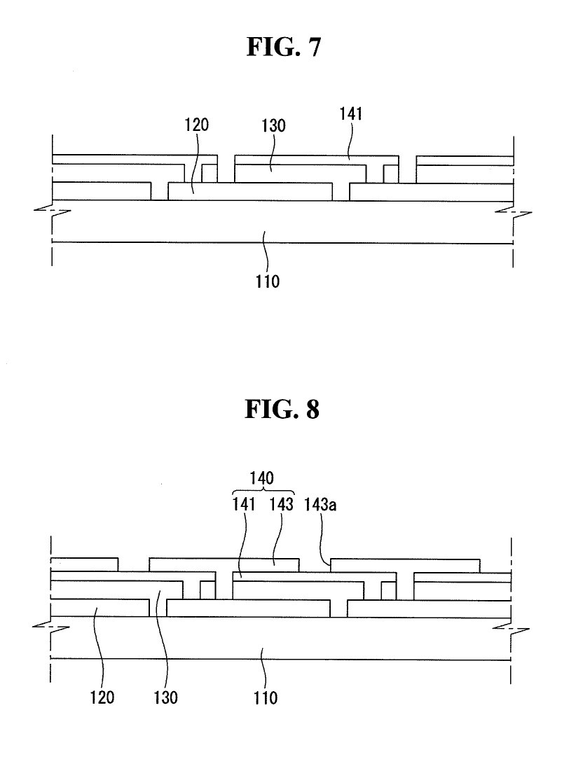

Subsequently, as shown in FIG. 7, the transparent conductive layer and the photoelectric conversion units 130 are patterned to form a plurality of first reflection layers 141 in the electricity generation region. The patterning process may be performed through a third scribing process.

Accordingly, when the third scribing process for irradiating a laser beam from the lower part of the substrate 110 toward the substrate 110 is performed, the TCO electrodes 120 of the electricity generation region are not evaporated, but the transparent conductive layer and the photoelectric conversion units 130 are evaporated and removed. Hence, the plurality of first reflection layers 141, which are spaced apart from one another at a uniform distance therebetween, are formed in the electricity generation region. Additionally, other portions of the TCO electrodes 120 are exposed thereby. In embodiments of the invention, the portions of the TCO electrodes 120 exposed by the second scribing process and the other portions of the TCO electrodes 120 exposed by the third scribing process are different.

As shown in FIG. 8, after the third scribing process is performed, a plurality of second reflection layers 143 each having an opening 143a are formed. The second reflection layers 143 are filled in portions removed by the third scribing process. Thus, the second reflection layers 143 are positioned in a space between adjacent cells. Additionally, the second reflection layers 143 are electrically connected to the TCO electrodes 120 thereby. In an embodiment of the invention, the second reflection layers 143 may be contacted to the exposed portions of the TCO electrodes 120, although such is not required.

The second reflection layer 143 is formed of a material obtained by mixing a medium with a white pigment that reflects light of a predetermined wavelength, for example, a long wavelength band equal to or longer than about 600 nm. The white pigment may contain at least one of an oxide, such as titanium dioxide (TiO₂) and barium sulfate (BaSO₄), a nitride, and a carbide. The second reflection layer 143 may contain one of a white paint containing the white pigment, a white foil, and ethyl vinyl acetate (EVA) foil.

The opening 143a may have various shapes such as a circle, a quadrangle, and a rectangle. As shown in FIG. 9, at least one opening 143a may be formed in one back electrode 150.

A width W1 of the opening 143a is less than a width W2 of the back electrode 150, and a length L1 of the opening 143a is less than a length L2 of the back electrode 150.

It is preferable, but not required, the width W1 and the length L1 of the opening 143a are large enough to form the second reflection layer 143 having the opening 143a using a screen printing method. When the second reflection layer 143 is formed using the screen printing method, a separate process for forming the opening 143a may be removed. Therefore, the manufacturing cost may be reduced.

The first reflection layers 141 and the second reflection layers 143 thus manufactured configure a back reflection layer 140.

After the back reflection layer 140 is formed, the plurality of back electrodes 150 are formed on the substrate 110. The back electrodes 150 are filled in the openings 143a. Thus, the back electrode 150 is electrically connected to the first reflection layer 141. Further, a back electrode 150 of one thin film solar cell is electrically connected to a TCO electrode 120 of another thin film solar cell adjacent to the one thin film solar cell through the first reflection layer 141.

The back electrode 150 may be formed using aluminum that is often cheaper than silver.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A thin film solar cell comprising:
a plurality of cells positioned on a substrate,
wherein each of the plurality of cells includes:
a first electrode positioned on one surface of the substrate;
at least one photoelectric conversion unit positioned on the first electrode;
a back reflection layer including a first reflection layer contacting the at least one photoelectric conversion unit and a second reflection layer having an opening exposing a portion of the first reflection layer, the second reflection layer contacting the first reflection layer; and
a second electrode positioned on the back reflection layer, the second electrode being electrically connected to the first reflection layer through the opening.

2. The thin film solar cell of claim 1, wherein the first reflection layer contains aluminum-doped zinc oxide (AZO) with conductivity or boron-doped zinc oxide (BZO) with conductivity.

3. The thin film solar cell of claim 2, wherein the second electrode contains aluminum contacting the first reflection layer through the opening.

4. The thin film solar cell of claim 3, wherein the first reflection layer has a thickness equal to or less than about 100 nm.

5. The thin film solar cell of claim 1, wherein the second reflection layer is formed of a material obtained by mixing a medium with a white pigment that reflects light of a long wavelength band equal to or longer than about 600 nm.

6. The thin film solar cell of claim 5, wherein the white pigment contains at least one of an oxide, a nitride, and a carbide.

7. The thin film solar cell of claim 6, wherein the oxide is at least one of titanium dioxide (TiO₂) and barium sulfate (BaSO₄).

8. The thin film solar cell of claim 6, wherein the second reflection layer contains one of a white paint containing the white pigment, a white foil, and ethyl vinyl acetate (EVA) foil.

9. The thin film solar cell of claim 5, wherein the opening has a circle shape, a quadrangle shape, or a rectangle shape.

10. The thin film solar cell of claim 9, wherein a width of the opening is less than a width of the second electrode.

11. The thin film solar cell of claim 9, wherein a length of the opening is less than a length of the second electrode.

12. The thin film solar cell of claim 9, wherein at least one opening is positioned on one second electrode.

13. A method for manufacturing a thin film solar cell comprising:
forming a first electrode on a substrate;
forming at least one photoelectric conversion unit on the first electrode;
forming a first reflection layer having conductivity on the at least one photoelectric conversion unit and forming a second reflection layer having an opening exposing a portion of the first reflection layer on the first reflection layer to thereby form a back reflection layer; and
forming a second electrode, that is electrically connected to the first reflection layer through the opening, on the second reflection layer.

14. The method of claim 13, wherein the first reflection layer is formed using aluminum-doped zinc oxide (AZO) or boron-doped zinc oxide (BZO).

15. The method of claim 13, wherein the second electrode is formed using aluminum.

16. The method of claim 13, wherein the first reflection layer is formed in a thickness equal to or less than about 100 nm.

17. The method of claim 13, wherein the second reflection layer is formed using a material obtained by mixing a medium with a white pigment reflecting light of a long wavelength band equal to or longer than about 600 nm.

18. The method of claim 17, wherein a width of the opening is less than a width of the second electrode.

19. The method of claim 17, wherein a length of the opening is less than a length of the second electrode.

20. The method of claim 17, wherein the white pigment contains at least one of an oxide, a nitride, and a carbide, and
the oxide is at least one of titanium dioxide (TiO₂) and barium sulfate (BaSO₄).
